(19) United States
(12) Patent Application Publication
(10) Pub. No.: US 2024/0347408 A1
(43) Pub. Date: Oct. 17, 2024

(54) SEMICONDUCTOR DEVICE

(71) Applicant: SUMITOMO ELECTRIC INDUSTRIES, LTD., Osaka (JP)

(72) Inventor: Masaki KIJIMA, Osaka (JP)

(21) Appl. No.: 18/293,919

(22) PCT Filed: Sep. 6, 2022
(86) PCT No.: PCT/JP2022/033369

§ 371 Date: Jan. 31, 2024

(30) Foreign Application Priority Data
Oct. 21, 2021 (JP) 2021-172674

(51) Int. Cl. H01L 23/31; H01L 23/29; H01L 29/16

(52) U.S. Cl. CPC H01L 23/3192; H01L 23/291; H01L 23/293; H01L 23/3171; H01L 29/1608

(57) ABSTRACT

A semiconductor device includes a substrate having a first principal surface, an electrode provided above the first principal surface, a first passivation layer covering the electrode and containing an inorganic material, and a second passivation layer formed on the first passivation layer and containing an organic material, wherein a first opening is formed in the first passivation layer to expose a portion of the electrode, a second opening is formed in the second passivation layer so as to be continuous with the first opening, and a second sidewall surface of the second opening is located inside a first sidewall surface of the first opening.

### TECHNICAL FIELD

The present disclosure relates to semiconductor devices.

This application is based upon and claims priority to Japanese Patent Application No. 2021-172674, filed on Oct. 21, 2021, the entire contents of which are incorporated herein by reference.

### BACKGROUND ART

There is a disclosed semiconductor device using a silicon nitride layer and a polyimide layer as a passivation layer formed on an electrode.

### PRIOR ART DOCUMENTS

### Patent Documents

Patent Document 1: Japanese Laid-Open Patent Publication No. H2-251158
Patent Document 2: Japanese Laid-Open Patent Publication No. S56-19639
Patent Document 3: Japanese Laid-Open Patent Publication No. H3-96243

### DISCLOSURE OF THE INVENTION

A semiconductor device according to the present disclosure includes a substrate having a first principal surface, an electrode provided above the first principal surface, a first passivation layer covering the electrode and containing an inorganic material, and a second passivation layer formed on the first passivation layer and containing an organic material, wherein a first opening is formed in the first passivation layer to expose a portion of the electrode, a second opening is formed in the second passivation layer so as to be continuous with the first opening, and a second sidewall surface of the second opening is located inside a first sidewall surface of the first opening.

### BRIEF DESCRIPTION OF THE DRAWINGS

FIG. 1 is a top view illustrating a semiconductor device according to an embodiment.

FIG. 2 is a cross sectional view illustrating the semiconductor device according to the embodiment.

FIG. 3 is a cross sectional view (part 1) illustrating a method for manufacturing the semiconductor device according to the embodiment.

FIG. 4 is a cross sectional view (part 2) illustrating the method for manufacturing the semiconductor device according to the embodiment.

FIG. 5 is a cross sectional view (part 3) illustrating the method for manufacturing the semiconductor device according to the embodiment.

FIG. 6 is a cross sectional view (part 4) illustrating the method for manufacturing the semiconductor device according to the embodiment.

### MODE OF CARRYING OUT THE INVENTION

### Problem to be Solved by the Present Disclosure

In a case where a plating layer is formed on a surface of an electrode, peeling of the plating layer may occur when a wire is bonded to the plating layer by wire-bonding.

One object of the present disclosure is to provide a semiconductor device capable of reducing peeling of a plating layer formed on a surface of an electrode.

### Effects of the Present Disclosure

According to the present disclosure, it is possible to reduce peeling of the plating layer formed on the surface of the electrode.

Embodiments of the present disclosure will be described below.

### DESCRIPTION OF EMBODIMENTS OF THE PRESENT DISCLOSURE

First, the embodiments of the present disclosure will be described below. In a crystallographic description in the present specification and drawings, an individual orientation is represented by [ ], a group orientation is represented by < >, an individual plane is represented by ( ) and a group plane is represented by { }. In addition, a negative crystallographic index is generally represented by “—” (bar) above the numeral, but in the present specification, a negative sign is added before the numeral.

[1] A semiconductor device according to one aspect of the present disclosure includes a substrate having a first principal surface, an electrode provided above the first principal surface, a first passivation layer covering the electrode and containing an inorganic material, and a second passivation layer formed on the first passivation layer and containing an organic material, wherein a first opening is formed in the first passivation layer to expose a portion of the electrode, a second opening is formed in the second passivation layer so as to be continuous with the first opening, and a second sidewall surface of the second opening is located inside a first sidewall surface of the first opening.

Because the second sidewall surface of the second electrode is located on an inner side of the first sidewall surface of the first electrode, when the plating layer is formed on the surface of the electrode, a portion of the plating layer becomes positioned between the electrode and the second passivation layer. Accordingly, when a wire is bonded to the plating layer, even if an external force acts on the plating layer in a direction to separate from the first principal surface, a force directed toward the first principal surface acts on the plating layer from the second passivation layer. For this reason, peeling of the plating layer can be reduced.

[2] In the semiconductor device of [1], in a cross section perpendicular to the first principal surface and the first side wall surface, a maximum value of a distance between the first sidewall surface and the second sidewall surface in a direction parallel to the first principal surface may be greater than or equal to 1 μm and less than or equal to 5 μm. If a maximum value of this distance were less than 1 μm, the portion of the second passivation layer that applies the force directed toward the first principal surface to the plating layer would become excessively small, and it may become difficult to reduce the peeling of the plating layer. On the other hand, if the maximum value of this distance were greater than 5 μm, it would become difficult to form the plating layer between the second passivation layer and the electrode, and a void may be generated.

[3] In the semiconductor device of [1] or [2], a portion of a lower surface of the first passivation layer may make contact with an upper surface of the electrode. In this case, a plating solution can easily be prevented from infiltrating along the surface of the electrode.

[4] In the semiconductor device of any one of [1] to [3], a thickness of the first passivation layer may be greater than or equal to 0.2 μm and less than or equal to 1.0 μm. If this thickness were less than 0.2 μm, the resistance to moisture may deteriorate. On the other hand, if this thickness were greater than 1.0 μm, a large stress may act on the substrate from the first passivation layer.

[5] In the semiconductor device of any one of [1] to [4], in a plan view viewed in a direction perpendicular to the first principal surface, the first opening may have a rounded rectangular shape with a minimum curvature radius greater than or equal to 10 μm and less than or equal to 100 μm at each of four corners thereof.

[6] In the semiconductor device of any one of [1] to [5], the first passivation layer may include a silicon nitride layer. In this case, an excellent resistance to moisture can easily be obtained.

[7] In the semiconductor device of any one of [1] to [6], the second passivation layer may include a polyimide layer. In this case, a suitable hardness can easily be obtained at the surface.

[8] In the semiconductor device of any one of [1] to [7], the substrate may be a silicon carbide substrate. In this case, an excellent withstand voltage can easily be obtained.

### EMBODIMENTS OF THE PRESENT DISCLOSURE

Hereinafter, embodiments of the present disclosure will be described in detail, but the present disclosure is not limited thereto. In the present specification and drawings, constituent elements having substantially the same functional configuration are designated by the same reference numerals, and a redundant description thereof may be omitted.

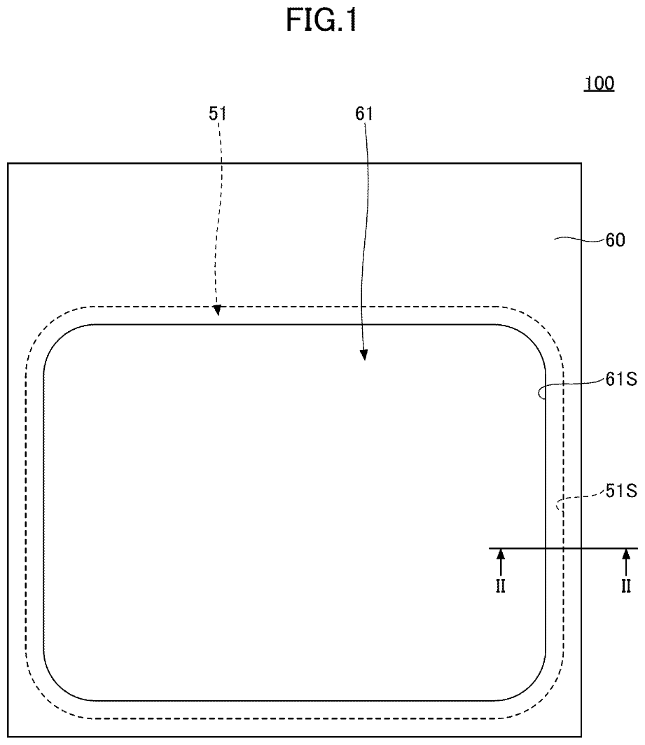

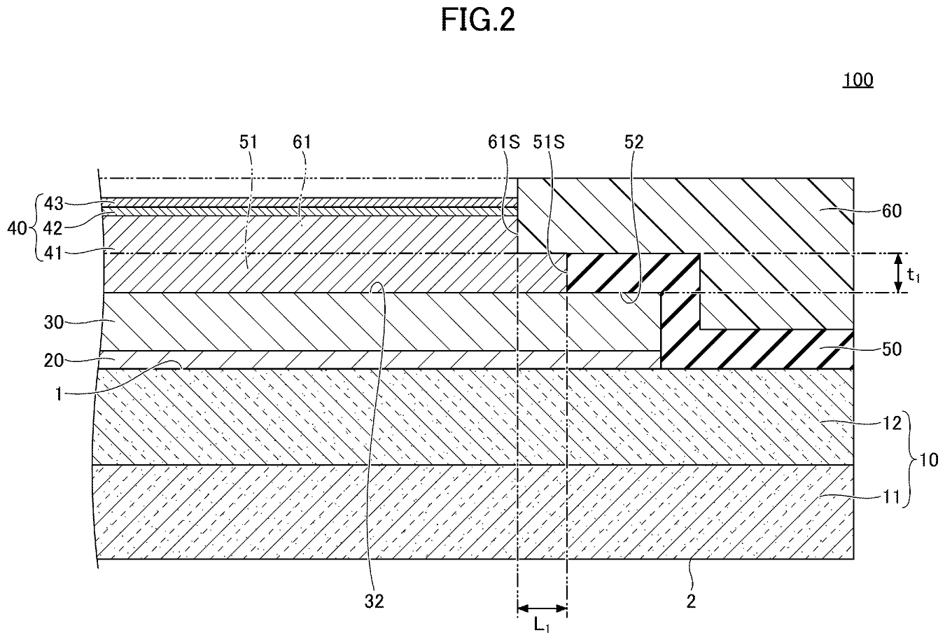

The present embodiment relates to a semiconductor device. FIG. 1 is a top view illustrating the semiconductor device according to an embodiment. FIG. 2 is a cross sectional view illustrating the semiconductor device according to the embodiment. FIG. 2 corresponds to a cross sectional view taken along a line II-II in FIG. 1.

As illustrated in FIG. 1 and FIG. 2, a semiconductor device 100 according to the embodiment may mainly include a substrate 10, an ohmic layer 20, an electrode 30, a plating layer 40, a first passivation layer 50, and a second passivation layer 60.

The substrate 10 is a silicon carbide substrate, for example. The substrate 10 includes a silicon carbide single crystal substrate 11, and a silicon carbide epitaxial layer 12 provided on the silicon carbide single crystal substrate 11, for example. The substrate 10 has a first principal surface 1, and a second principal surface 2 opposite to the first principal surface 1. The silicon carbide epitaxial layer 12 forms the first principal surface 1, and the silicon carbide single crystal substrate 11 forms the second principal surface 2. The silicon carbide single crystal substrate 11 and the silicon carbide epitaxial layer 12 are composed of hexagonal silicon carbide of polytype 4H, for example. A plurality of semiconductor regions into which impurities are introduced may be formed in the silicon carbide epitaxial layer 12. A semiconductor element, such as a field effect transistor or the like, is formed on the substrate 10.

The first principal surface 1 is a {0001} plane or a plane inclined from the {0001} plane by an off angle of 8° or less in an off direction. Preferably, the first principal surface 1 is a (000-1) plane or a plane inclined from the (000-1) plane by an off angle of 8° or less in the off direction. The off direction may be a <11-20> direction, or a <1-100> direction, for example. The off angle may be 1° or greater, or 2° or greater, for example. The off angle may be 6° or less, or 4° or less.

The ohmic layer 20 is selectively formed on first principal surface 1, and makes ohmic contact with a portion of silicon carbide epitaxial layer 12. The ohmic layer 20 is composed of a material including nickel silicide (NiSi), for example. The ohmic layer 20 may be composed of a material including titanium (Ti), aluminum, and silicon.

The electrode 30 is formed on the ohmic layer 20. The electrode 30 is an aluminum electrode, for example. The electrode 30 is electrically connected to the substrate 10 through the ohmic layer 20.

The first passivation layer 50 includes an inorganic material. The first passivation layer 50 is formed on the silicon carbide epitaxial layer 12, and covers a portion of the electrode 30. A first opening 51 is formed in the first passivation layer 50. The first opening 51 is formed above the electrode 30, and a portion of the electrode 30 is exposed through the first opening 51. The first passivation layer 50 includes a silicon nitride (SiN) layer, for example. The first passivation layer 50 may be a silicon nitride layer. The first opening 51 has a first sidewall surface 51S. The first sidewall surface 51S may be perpendicular to the first principal surface 1, or may be inclined from a plane perpendicular to the first principal surface 1. A portion of a lower surface 52 of the first passivation layer 50 makes contact with an upper surface 32 of the electrode 30.

The second passivation layer 60 includes an organic material. The second passivation layer 60 is formed on the first passivation layer 50. A second opening 61, continuous with the first opening 51, is formed in the second passivation layer 60. The second opening 61 is formed on the first passivation layer 50, and a portion of the first passivation layer 50 and a portion of the electrode 30 are exposed through the second opening 61. The second opening 61 has a second sidewall surface 61S. In a plan view viewed in a direction perpendicular to the first principal surface 1, second sidewall surface 61S is located on an inner side of the first sidewall surface 51S. The second sidewall surface 61S may be perpendicular to the first principal surface 1, or may be inclined from a plane perpendicular to the first principal surface 1. The second passivation layer 60 includes a polyimide layer, for example. The second passivation layer 60 may be a polyimide layer.

The plating layer 40 includes a nickel (Ni) plating layer 41, a palladium (Pd) plating layer 42, and a gold (Au) plating layer 43. A portion of the plating layer 40 is located between the electrode 30 and the second passivation layer 60 in the direction perpendicular to the first principal surface 1. The Ni plating layer 41 is formed on the electrode 30 on an inner side of the first opening 51 and the second opening 61. A portion of the Ni plating layer 41 is located between the electrode 30 and the second passivation layer 60 in the direction perpendicular to the first principal surface 1. The Ni plating layer 41 may include phosphorus (P). The Pd plating layer 42 is formed on the Ni plating layer 41 on the inner side of the second opening 61. The Au plating layer 43 is formed on the Pd plating layer 42 on the inner side of the second opening 61. A thickness of the Ni plating layer 41 is preferably greater than or equal to 3.0 μm and less than or equal to 7.0 μm, and more preferably greater than or equal to 4.0 μm and less than or equal to 6.0 μm. A thickness of the Pd plating layer 42 is preferably greater than or equal to 20 nm and less than or equal to 40 nm, and more preferably greater than or equal to 25 nm and less than or equal to 35 nm. A thickness of the Au plating layer 43 is preferably greater than or equal to 30 nm and less than or equal to 70 nm, and more preferably greater than or equal to 40 nm and less than or equal to 60 nm.

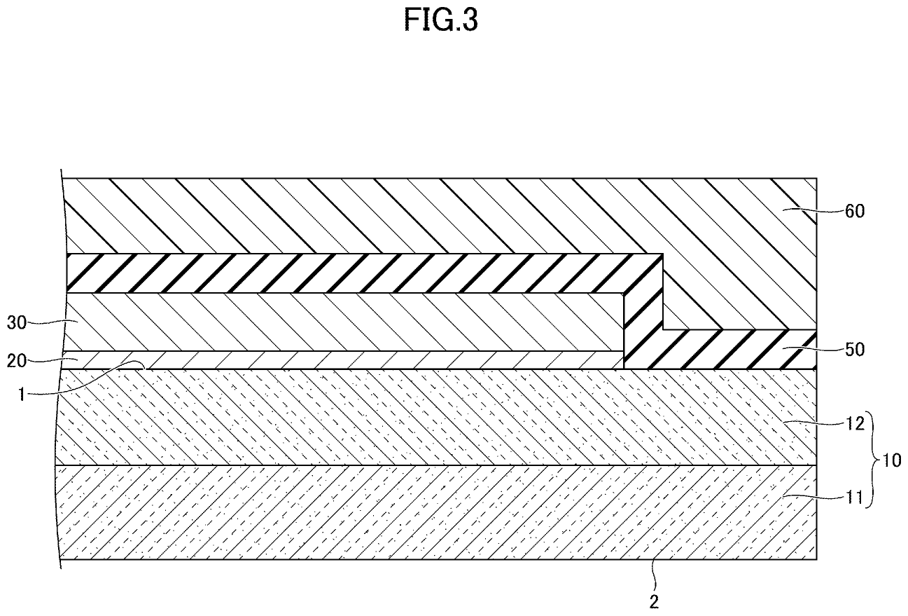

Next, a method for manufacturing the semiconductor device 100 according to the embodiment will be described. FIG. 3 through FIG. 6 are cross sectional views illustrating the method for manufacturing the semiconductor device 100 according to the embodiment.

First, as illustrated in FIG. 3, the substrate 10 is prepared. When preparing the substrate 10, the silicon carbide epitaxial layer 12 is formed on the silicon carbide single crystal substrate 11. Next, various semiconductor regions are formed in the silicon carbide epitaxial layer 12 by ion implantation or the like. Next, the ohmic layer 20 is formed on the first principal surface 1, and the electrode 30 is formed on the ohmic layer 20. Next, the first passivation layer 50 is formed on the first principal surface 1, so as to cover the ohmic layer 20 and the electrode 30. For example, a silicon nitride layer is formed as the first passivation layer 50. Next, the second passivation layer 60 is formed on the first passivation layer 50. For example, a polyimide layer is formed as the second passivation layer 60.

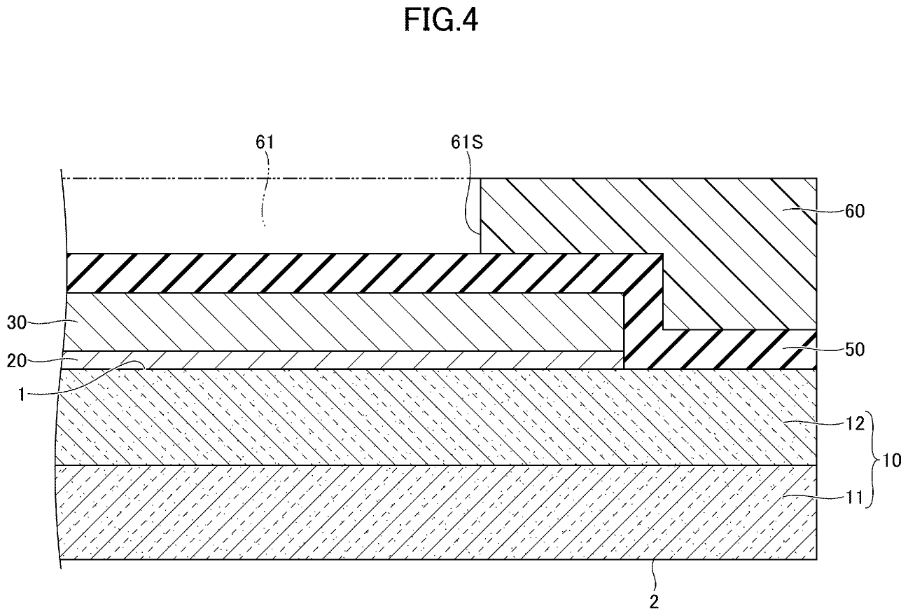

Next, as illustrated in FIG. 4, the second opening 61 is formed in the second passivation layer 60. The second opening 61 has a second sidewall surface 61S. For example, in a case where the second passivation layer 60 is a photosensitive polyimide layer, the second opening 61 may be formed by exposing and developing the second passivation layer 60.

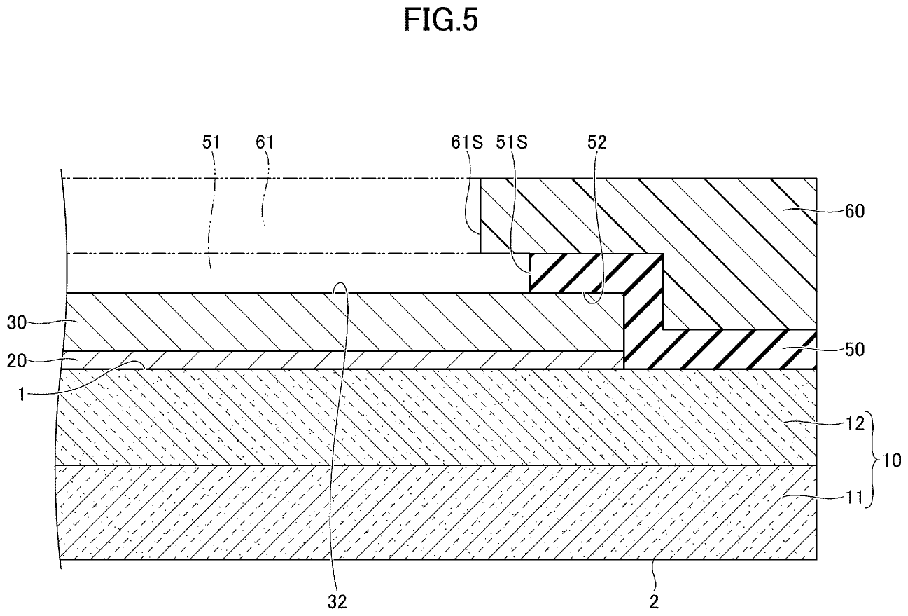

Next, as illustrated in FIG. 5, the first opening 51 is formed in the first passivation layer 50 by etching the first passivation layer 50. For example, a dry etching using a gas mixture of tetrafluoromethane (CF₄) and oxygen (O₂), without applying a bias voltage, may be performed for this etching. This etching is an isotropic etching, for example. The first opening 51 is formed so that, in the plan view viewed in the direction perpendicular to the first principal surface 1, the first sidewall surface 51S is located on an outer side of the second sidewall surface 61S, and a portion of the lower surface 52 of the first passivation layer 50 makes contact with the upper surface 32 of the electrode 30, for example.

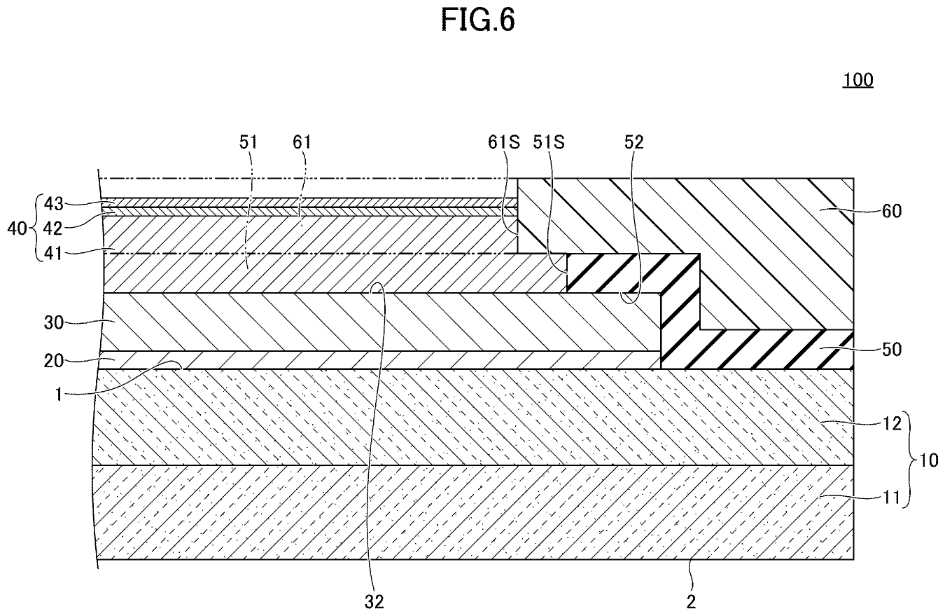

Next, as illustrated in FIG. 6, the plating layer 40 is formed. When forming the plating layer 40, the Ni plating layer 41, the Pd plating layer 42, and the Au plating layer 43 are formed in this order using a plating solution, respectively. The Ni plating layer 41 is formed so that a portion of the Ni plating layer 41 enters in between the electrode 30 and the second passivation layer 60 in the direction perpendicular to the first principal surface 1.

The semiconductor device 100 according to the embodiment can be manufactured in the manner described above.

In the present embodiment, the second sidewall surface 61S of the second opening 61 is located on the inner side of the first sidewall surface 51S of the first opening 51. For this reason, when the plating layer 40 is formed on the surface of the electrode 30, a portion of the plating layer 40, for example, a portion of the Ni plating layer 41 becomes positioned between the electrode 30 and the second passivation layer 60 in the direction perpendicular to the first principal surface 1, for example. Accordingly, even if an external force acts on the plating layer 40 in a direction to separate from the first principal surface 1 when a wire is bonded to the plating layer 40, a force directed toward the first principal surface 1 acts on the plating layer 40 from the second passivation layer 60. For this reason, peeling of the plating layer 40 can be reduced.

An excellent resistance to moisture can be obtained by including a silicon nitride layer in the first passivation layer 50. In addition, a suitable hardness can be obtained at the surface, by including a polyimide layer in the second passivation layer 60. Further, an excellent withstand voltage can be obtained by including a silicon carbide substrate in the substrate 10.

Because a portion of the lower surface 52 of the first passivation layer 50 makes contact with the upper surface 32 of the electrode 30, the plating solution can easily be prevented from infiltrating along the surface of the electrode 30.

In a cross section perpendicular to the first principal surface 1 and the first sidewall surface 51S, a maximum value of a distance L₁ between first sidewall surface 51S and second sidewall surface 61S in a direction parallel to the first principal surface 1 is preferably greater than or equal to 1 μm and less than or equal to 5 μm. If the maximum value of the distance L₁ were less than 1 μm, the portion of the second passivation layer 60 that applies the force directed toward the first principal surface 1 to the plating layer 40 would become excessively small, and it may become difficult to reduce the peeling of the plating layer 40. On the other hand, if the maximum value of the distance L₁ were greater than 5 μm, it would become difficult to form the plating layer 40 between the second passivation layer 60 and the electrode 30, and a void may be generated. The maximum value of the distance L₁ is more preferably greater than or equal to 2 μm and less than or equal to 4 μm.

A thickness t₁ of the first passivation layer is preferably greater than or equal to 0.2 μm and less than or equal to 1.0 μm. If the thickness t₁ were less than 0.2 μm, the resistance to moisture may deteriorate. If the thickness t₁ were greater than 1.0 μm, a large stress may act on the substrate 10 from the first passivation layer 50. On the other hand, the thickness t₁ is more preferably greater than or equal to 0.3 μm and less than or equal to 0.9 μm, and still more preferably greater than or equal to 0.4 μm and less than or equal to 0.8 μm.

As illustrated in FIG. 1, in the plan view viewed in the direction perpendicular to the first principal surface 1, the first opening 51 and the second opening 61 may have a rounded rectangular shape, respectively. A minimum curvature radius at each of the four corners of the first opening 51 is preferably greater than or equal to 10 μm and less than or equal to 100 μm. If this minimum curvature radius were less than 10 μm, stress would likely be concentrated at the corner portion, and a crack may occur in the first passivation layer 50. On the other hand, if the minimum curvature radius were greater than 100 μm, an excessively large portion of the electrode 30 may become covered with the first passivation layer 50. This minimum curvature radius is more preferably greater than or equal to 20 μm and less than or equal to 90 μm, and still more preferably greater than or equal to 30 μm and less than or equal to 80 μm.

Although the embodiments are described above in detail, the present disclosure is not limited to a specific embodiment, and various variations and modifications can be made without departing from the scope described in the claims.

### DESCRIPTION OF REFERENCE NUMERALS

1: First principal surface
2: Second principal surface
10: Substrate
11: Silicon carbide single crystal substrate
12: Silicon carbide epitaxial layer
20: Ohmic layer
30: Electrode
32: Upper surface
40: Plating layer
41: Ni plating layer
42: Pd plating layer
43: Au plating layer
50: First passivation layer
51: First opening
51S: First side wall surface
52: Lower surface
60: Second passivation layer
61: Second opening
61S: Second side wall surface
100: Semiconductor device

1. A semiconductor device comprising:
a substrate having a first principal surface;
an electrode provided above the first principal surface;
a first passivation layer covering the electrode and containing an inorganic material; and
a second passivation layer formed on the first passivation layer and containing an organic material, wherein
a first opening is formed in the first passivation layer to expose a portion of the electrode,
a second opening is formed in the second passivation layer so as to be continuous with the first opening, and
a second sidewall surface of the second opening is located inside a first sidewall surface of the first opening.

2. The semiconductor device as claimed in claim 1, wherein
in a cross section perpendicular to the first principal surface and the first side wall surface,
a maximum value of a distance between the first sidewall surface and the second sidewall surface in a direction parallel to the first principal surface is greater than or equal to 1 μm and less than or equal to 5 μm.

3. The semiconductor device as claimed in claim 1, wherein a portion of a lower surface of the first passivation layer makes contact with an upper surface of the electrode.

4. The semiconductor device as claimed in claim 1, wherein a thickness of the first passivation layer is greater than or equal to 0.2 μm and less than or equal to 1.0 μm.

5. The semiconductor device as claimed in claim 1, wherein in a plan view viewed in a direction perpendicular to the first principal surface, the first opening has a rounded rectangular shape with a minimum curvature radius greater than or equal to 10 μm and less than or equal to 100 μm at each of four corners thereof.

6. The semiconductor device as claimed in claim 1, wherein the first passivation layer includes a silicon nitride layer.

7. The semiconductor device as claimed in claim 1, wherein the second passivation layer includes a polyimide layer.

8. The semiconductor device as claimed claim 1, wherein the substrate is a silicon carbide substrate.
